(19) United States
(12) Patent Application Publication
(10) Pub. No.: US 2020/0163255 A1
(43) Pub. Date: May 21, 2020

(54) HIGHLY ELASTIC, THERMALLY CONDUCTIVE AND OPTICALLY TRANSPARENT POLYMER BASED MATERIAL FOR HEAT DISSIPATION IN FLEXIBLE/WEARABLE ELECTRONICS AND OTHER THERMAL MANAGEMENT APPLICATIONS

(71) Applicants: Jiahua ZHU, Fairlawn, OH (US); Nitin Mehra, Oceanside, CA (US)

(72) Inventors: Jiahua ZHU, Fairlawn, OH (US); Nitin Mehra, Oceanside, CA (US)

(73) Assignee: THE UNIVERSITY OF AKRON, AKRON, OH (US)

(21) Appl. No.: 16/686,322

(22) Filed: Nov. 18, 2019

Related U.S. Application Data
(60) Provisional application No. 62/768,297, filed on Nov. 16, 2018.

(51) Int. Cl. H05K 7/20; F28F 21/06; F28F 21/04; B32B 27/08

(52) U.S. Cl. CPC H05K 7/20481; F28F 21/067; F28F 21/04; B32B 2307/51; B32B 2307/302; B32B 2307/412; B32B 27/08

(57) ABSTRACT

In various embodiments, the present invention is directed to polymer based heat dissipating materials and films that are highly elastic, thermally conductive and optically transparent and made using a non-conventional approach. The polymer based heat dissipating materials and films of the present invention use a hybrid filler comprising a very small loading of traditional fillers like boron nitride or graphene oxide combined with non-conventional fillers like organic linkers, dispersed in a preferably non-conductive polymer matrix. These hybrid fillers provide an elastic thermal network that drives heat conduction across the polymer chains, while provided flexibility and optical clarity.

### CROSS REFERENCE TO RELATED APPLICATIONS

This application claims the benefit of U.S. provisional patent application Ser. No. 62/768,297 entitled “Highly Elastic, Thermally Conductive and Optically Transparent Polymer Based Material for Heat Dissipation in Flexible/Wearable Electronics and Other Thermal Management Applications,” filed Nov. 16, 2018, and incorporated herein by reference in its entirety.

### FIELD OF THE INVENTION

One or more embodiments of the present invention relates to a material for heat dissipation. In certain embodiments, the present invention is directed to flexible, optically clear materials material for heat dissipation having hybrid filler materials.

### BACKGROUND OF THE INVENTION

Flexible heat dissipating plastics are highly sought after materials due to the rapid advancement in flexible electronics and the electronic packaging industry. One of the crucial challenges that come with such systems is keeping them cool, which in turn enhances both their reliability and lifespan. Heat dissipating materials play a very important role to address this challenge. It is estimated that Global Thermal Management technology market is USD 11.7 Billion (2015). Out of this Thermal Interface Materials based on Polymer composite is currently estimated around USD 667.5 million. (BCC Market Report). These materials have both economic and technological value.

Electronic devices mounted on the flexible plastics and today's high computing processors require good thermally conductive to effectively channel heat out and away from the electronics. Moreover, the growing trend in flexible electronics and processors has been reduced size and increased performance, providing increased functionality in small size. High computing power and other features (generating heat) in a small package created additional problems with thermal management that must be addressed to permit further increases in system performance and reliability for power electronics. Development of new thermally conductive materials that have electrically insulating properties is critical to address this problem.

One of the major drawbacks of today's thermally conductive materials is that they lack elasticity. Due to high loading of traditional fillers (ceramic/metallic/carbon) material becomes brittle. Although they have good thermal conductivity, their lack of flexibility limits their application in areas where elasticity forms an important factor. Along with elasticity, such materials are required to be light weight, particularly for use in wearable electronics. Most present heat dissipating materials have high specific density and are optically non-transparent, as a high loading of traditional generally opaque fillers are required.

Accordingly, what is needed in the art is a heat dissipating material that is thermally conductive, mechanically elastic and optically transparent.

### SUMMARY OF THE INVENTION

In various aspects, the present invention is directed to a cost effective, light weight heat dissipating material that is thermally conductive, mechanically elastic and optically transparent. These materials are highly elastic compared currently available materials and are believed to be sufficiently flexible to work in flexible electronics applications. These materials do not require a high loading of traditional fillers, which can be highly expensive, can easily be fabricated into various shapes and sizes, and are non-corrosive. Moreover, in one or more embodiments, the heat dissipating materials of the present invention are optically transparent and can be used in a wide range of applications for which the opaque heat dissipating materials of the prior art are unsuitable. The number of applications for these materials ranges from electronics to energy to automobiles to aerospace.

In a first aspect, the present invention is directed to a flexible heat dissipating composition comprising: a substantially electrically non-conductive polymer comprising one or more functional groups capable of forming hydrogen or ionic bonds; and a hybrid filler comprising: one or more ceramic 2D nanosheets surface functionalized with one or more functional groups capable of forming hydrogen or ionic bonds; and one or more organic molecules having two functional groups capable of forming hydrogen or ionic bonds. In one or more of these embodiments, the substantially electrically non-conductive polymer, one or more ceramic 2D nanosheets, and one or more organic molecules are connected to each other by hydrogen bonds to form an interpenetrating network. In one or more embodiments, the flexible heat dissipating composition of the present invention includes any one or more of the above referenced embodiments of the first aspect of the present invention wherein the composition is optically transparent.

In one or more embodiments, the flexible heat dissipating composition of the present invention includes any one or more of the above referenced embodiments of the first aspect of the present invention wherein the substantially electrically non-conductive polymer is selected from the group consisting of poly(vinyl alcohol), polyvinyl propylene, polyether, polyamide, polyacrylic amides, polysaccharides, polyacrylic acids, polyurethanes with polyethylene glycol ether soft segments, and combinations, copolymers and grafts thereof. In one or more embodiments, the flexible heat dissipating composition of the present invention includes any one or more of the above referenced embodiments of the first aspect of the present invention wherein the one or more functional groups capable of forming hydrogen or ionic bonds in the substantially electrically non-conductive polymer are selected from hydroxyl groups, carboxyl groups, amine groups, thiol groups, and combinations thereof. In one or more embodiments, the flexible heat dissipating composition of the present invention includes any one or more of the above referenced embodiments of the first aspect of the present invention wherein the one or more ceramic 2D nanosheets comprise boron nitride, carbon, graphene oxide (GO), molybdenum disulfide or a combination thereof.

In one or more embodiments, the flexible heat dissipating composition of the present invention includes any one or more of the above referenced embodiments of the first aspect of the present invention wherein the one or more ceramic 2D nanosheets have a thickness of from about 2 nM to about 30 nM. In one or more embodiments, the flexible heat dissipating composition of the present invention includes any one or more of the above referenced embodiments of the first aspect of the present invention wherein the one or more ceramic 2D nanosheets have a length of from about 250 nM to about 1500 nM. In one or more embodiments, the flexible heat dissipating composition of the present invention includes any one or more of the above referenced embodiments of the first aspect of the present invention wherein the one or more ceramic 2D nanosheets comprise from about 0.1 to about 5 weight percent of the flexible heat dissipating composition.

In one or more embodiments, the flexible heat dissipating composition of the present invention includes any one or more of the above referenced embodiments of the first aspect of the present invention wherein the one or more organic molecules comprise a C₂-C₆ linear alkane having a first end comprising a hydroxyl functional group and a second end comprising an amine functional group. In one or more embodiments, the flexible heat dissipating composition of the present invention includes any one or more of the above referenced embodiments of the first aspect of the present invention wherein the one or more organic molecules is selected from the group consisting of ethanolamine, ethylene diamine, ethylene glycol, diethylene glycol, tetra ethylene glycol, hexaethylene glycol, dicarboxylic acids, crystalline sugars, amino acids, and combinations thereof. In one or more embodiments, the flexible heat dissipating composition of the present invention includes any one or more of the above referenced embodiments of the first aspect of the present invention wherein the one or more organic molecules comprise from about 5 to about 60 weight percent (wt %) of the flexible heat dissipating composition.

In one or more embodiments, the flexible heat dissipating composition of the present invention includes any one or more of the above referenced embodiments of the first aspect of the present invention having a thermal conductivity of from about 0.4 W/m·K to about 1.0 W/m·K. In one or more embodiments, the flexible heat dissipating composition of the present invention includes any one or more of the above referenced embodiments of the first aspect of the present invention having an elongation of from about 50% to about 500%.

In a second aspect, the present invention is directed to a flexible, optically transparent heat dissipating film or coating comprising the flexible heat dissipating composition described herein. In one or more of these embodiments, the flexible, optically transparent heat dissipating film or coating comprises from about 0.2 wt % to about 5 wt % boron nitride and from about 20 wt % to about 40 wt % ethanolamine. In one or more embodiments, the flexible, optically transparent heat dissipating film or coating of the present invention includes any one or more of the above referenced embodiments of the second aspect of the present invention wherein the flexible, optically transparent heat dissipating film or coating is a free-standing film. In one or more embodiments, the flexible, optically transparent heat dissipating film or coating of the present invention includes any one or more of the above referenced embodiments of the second aspect of the present invention having a thickness of from about 10 microns to 1 cm to about 80 nM. In one or more embodiments, the flexible, optically transparent heat dissipating film or coating of the present invention includes any one or more of the above referenced embodiments of the second aspect of the present invention formed by solvent casting dip coating, doctor blade casting, or spin coating.

In a third aspect, the present invention is directed to a method for producing the flexible heat dissipating composition described herein, comprising: selecting a substantially electrically non-conductive polymer having one or more functional groups capable of forming hydrogen or ionic bonds; dissolving the substantially electrically non-conductive polymer in a suitable solvent; preparing ceramic 2D nanosheets surface functionalized with one or more functional groups capable of forming hydrogen or ionic bonds; selecting a suitable organic filler material having at least two functional groups capable of forming hydrogen or ionic bonds; adding the ceramic 2D nanosheets and the organic filler material to the substantially electrically non-conductive polymer solution and stirring or agitating for from about 0.5 hours to about 5 hours at a temperature of from about 40° C. to about 80° C. to form the flexible heat dissipating composition described herein. In one or more of these embodiments, the step of stirring or agitating comprises stirring or agitation for from about 0.5 hours to about 5 hours at a temperature of from about 40° C. to about 80° C.

In one or more embodiments, the method for producing the flexible heat dissipating composition of the present invention includes any one or more of the above referenced embodiments of the third aspect of the present invention wherein the substantially electrically non-conductive polymer is selected from the group consisting of polyvinyl alcohol, polyvinyl propylene, polyether, polyamide, polyacrylic amides, polysaccharides, polyacrylic acids, polyurethanes with polyethylene glycol ether soft segments, and combinations, copolymers, or graft thereof. In one or more embodiments, the method for producing the flexible heat dissipating composition of the present invention includes any one or more of the above referenced embodiments of the third aspect of the present invention wherein the substantially electrically non-conductive polymer in polyvinyl alcohol and the step of dissolving the substantially electrically non-conductive polymer comprises dissolving polyvinyl alcohol in deionized water at about 90° C. to about 95° C. for from 0.5 to about 5 hours or until the solution becomes clear. In one or more embodiments, the method for producing the flexible heat dissipating composition of the present invention includes any one or more of the above referenced embodiments of the third aspect of the present invention wherein the ceramic 2D nanosheets comprise a ceramic material selected from the group consisting of boron nitride, carbon, graphene oxide (GO), molybdenum disulfide, and combinations thereof.

In one or more embodiments, the method for producing the flexible heat dissipating composition of the present invention includes any one or more of the above referenced embodiments of the third aspect of the present invention wherein the ceramic 2D nanosheets comprise boron nitride and the step of preparing the ceramic 2D nanosheets comprises: combining hexagonal boron nitride with NaOH and ball milling for from 1 to about 24 hours at a speed of from about 200 RPM to about 700 RPM to form a slurry; removing the dissolved NaOH from the slurry; subjecting the product to ultra-sonication in water for about 1 hour; centrifuging the ultra-sonicated product and collecting the supernatant containing the boron nitride 2D nanosheets surface functionalized with one or more functional groups capable of forming hydrogen or ionic bonds.

In one or more embodiments, the method for producing the flexible heat dissipating composition of the present invention includes any one or more of the above referenced embodiments of the third aspect of the present invention, wherein the organic filler material comprises an organic material selected from the group consisting of ethanolamine, ethylene diamine, ethylene glycol, diethylene glycol, tetra ethylene glycol, hexaethylene glycol, dicarboxylic acids, crystalline sugars, amino acids, and combinations thereof.

In a fourth aspect, the present invention is directed to a method for producing a flexible, optically transparent heat dissipating film comprising the optically transparent flexible heat dissipating composition described herein comprising: dissolving a polymer selected from the group consisting of poly(vinyl alcohol), polyvinyl propylene, polyether, polyamide, polyacrylic amides, polysaccharides, polyacrylic acids, polyurethanes with polyethylene glycol ether soft segments, and combinations, copolymers, or graft thereof in a suitable solvent to obtain a clear polymer solution; preparing 2D nanosheets comprising one or more of boron nitride, carbon, graphene oxide (GO), and molybdenum disulfide, the 2D nanosheets being surface functionalized with one or more functional groups capable of forming hydrogen or ionic bonds; adding from 0.1 wt % to about 5 wt % the 2D nanosheets and from 5 wt % to about 60 wt % of an organic filler material comprising an organic compound selected from the group consisting of ethanolamine, ethylene diamine, ethylene glycol, diethylene glycol, tetra ethylene glycol, hexaethylene glycol, dicarboxylic acids, crystalline sugars, amino acids, and combinations thereof to the clear polymer solution and stirring or agitating for from about 0.5 hours to about 5 hours at a temperature of from about 40° C. to about 80° C. to form the optically clear flexible heat dissipating composition of described herein; pouring the optically clear flexible heat dissipating composition of into a flat-bottomed container or onto a surface and drying it at a temperature of from about 25° C. to about 60° C. for from 1 to 7 days to form a freestanding film; and heating the freestanding film at a temperature of from about 40° C. to about 80° C. for from 1 to 24 hours to remove any remaining solvent.

### BRIEF DESCRIPTION OF THE DRAWINGS

For a more complete understanding of the features and advantages of the present invention, reference is now made to the detailed description of the invention along with the accompanying figures in which:

FIG. 1 is a graph showing the thermal conductivity (TC) of thermally conductive materials according to the present invention with different weight percentages (wt %) of exfoliated boron nitride (BN) and ethanolamine (EA) in polyvinyl alcohol (PVA).

FIG. 2 is a graph showing the thermal conductivity of thermally conductive materials according to the present invention at 1.0 wt % and 0.5 wt % of BN and different loadings EA in PVA.

FIG. 3 is a graph showing the results of mechanical testing of thermally conductive materials according to the present invention at 0.5 wt % of BN and with different loadings of EA in PVA.

FIG. 4 is a graph showing the results of mechanical testing of thermally conductive materials according to the present invention at 1.0 wt % of BN and with different loadings of EA in PVA.

FIG. 5 is a comparison of Fourier Transform Infrared Spectroscopy (FTIR) spectra of thermally conductive materials according to the present invention at 0.5 wt. % of BN and different loadings of EA in PVA.

FIG. 6 is an XRD diffraction of thermally conductive materials according to the present invention at BN 0.5 and different loadings of EA in PVA.

FIG. 7 is a series of optical photos comparing thermally conductive materials according to the present invention at BN 0.5 and with different loadings of EA in PVA.

### DETAILED DESCRIPTION OF THE ILLUSTRATIVE EMBODIMENTS

The following is a detailed description of the disclosure provided to aid those skilled in the art in practicing the present disclosure. Those of ordinary skill in the art may make modifications and variations in the embodiments described herein without departing from the spirit or scope of the present disclosure. Unless otherwise defined, all technical and scientific terms used herein have the same meaning as commonly understood by one of ordinary skill in the art to which this disclosure belongs. The terminology used in the description of the disclosure herein is for describing particular embodiments only and is not intended to be limiting of the disclosure.

In various embodiments, the present invention is directed to polymer based heat dissipating materials and films that are highly elastic, thermally conductive and optically transparent and made using a non-conventional approach. The polymer based heat dissipating materials and films of the present invention use a hybrid filler comprising a very small loading of traditional fillers like boron nitride or graphene oxide combined with non-conventional fillers like organic linkers, dispersed in a preferably non-conductive polymer matrix. The hybrid fillers provide an elastic thermal network that drives heat conduction across polymer chains while provided flexibility and optical clarity. It is believed that these materials pave a way for new sets of elastic heat dissipating materials for wide spectrum of applications including, but not limited to, flexible or wearable electronics and electronic packaging.

The following terms may have meanings ascribed to them below, unless specified otherwise. As used herein, the terms “comprising” “to comprise” and the like do not exclude the presence of further elements or steps in addition to those listed in a claim. Similarly, the terms “a,” “an” or “the” before an element or feature does not exclude the presence of a plurality of these elements or features, unless the context clearly dictates otherwise.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from context, all numerical values provided herein in the specification and the claim can be modified by the term “about.”

It should be also understood that the ranges provided herein are shorthand for all of the values within the range and, further, that the individual range values presented herein can be combined to form additional non-disclosed ranges. For example, a range of 1 to 50 is understood to include any number, combination of numbers, or sub-range from the group consisting 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50.

All publications, patent applications, patents, and other references mentioned herein are expressly incorporated by reference in their entirety, which means that they should be read and considered by the reader as part of this text. That the document, reference, patent application, or patent cited in this text is not repeated in this text is merely for reasons of conciseness. In the case of conflict, the present disclosure, including definitions, will control. All technical and scientific terms used herein have the same meaning.

Further, any compositions or methods provided herein can be combined with one or more of any of the other compositions and methods provided herein. The fact that given features, elements or components are cited in different dependent claims does not exclude that at least some of these features, elements or components maybe used in combination together.

In a first aspect, the present invention is directed to a flexible heat dissipating composition comprising a polymer having one or more functional groups capable of forming hydrogen or ionic bonds and a hybrid filler composed of a 2D nanosheets made from a ceramic, carbon, or similar filler material having or functionalized to have with one or more functional groups capable of forming hydrogen or ionic bonds and one or more organic molecules having two different functional groups capable of forming hydrogen or ionic bonds. As will be apparent, the hybrid filler material is dispersed within a polymer matrix. In these embodiments, the polymer, 2D nanosheets, and organic molecules are connected to each other by hydrogen bonds to form an interpenetrating network that is flexible and depending upon the loading of the filler material optically clear.

Because most applications for the heat dissipating polymer compositions of the present invention are electrical or electronic in nature, it is strongly preferred, but not absolutely required, that the polymer forming the matrix of the composition be substantially electrically non-conductive. As used herein, the term “substantially electrically non-conductive” is used to refer to a polymer that does not conduct essentially any electricity under normal operating conditions. In embodiments where the heat dissipating polymer composition of the present invention is being used in connection with a computer, a flexible electronic device or other electronic device, use of a substantially electrically non-conductive polymer to form the matrix of the material is advantageous to prevent short circuits of the electronic device through the heat dissipating polymer composition. This feature is, of course, of much less importance where the application for the heat dissipating polymer composition does not involve electronics or electricity.

The polymer chosen for the polymer matrix of the present invention will contain, or be functionalized to contain, one or more groups that are capable of forming hydrogen or ionic bonds. Suitable functional groups may include, without limitation, hydroxyl groups, carboxyl groups, amine groups, thiol groups, or any combinations thereof. Suitable polymers may include poly(vinyl alcohol), polyvinyl propylene, polyether, polyamide, polyacrylic amides, polysaccharides, polyacrylic acids, polyurethanes with polyethylene glycol ether soft segments, or any combination, copolymer of graft polymer thereof.

The molecular weight of the polymers used for the present invention is not particularly limited in that present invention does not require any particular accommodation with respect to molecular weight. As will be apparent, the molecular weights of the polymers chosen will depend upon the particular polymer being used and the particular application. One of ordinary skill in the art will be able to select a suitable polymer for a particular application and determine a suitable molecular weight for that polymer without undue experimentation.

Similarly, the glass transition temperature (T_{g}) and degradation temperature (T_{d}) are not particularly limited in that present invention does not require any particular accommodation with respect to these factors. As will be apparent, the T_{g} and T_{d} of the polymers selected for the present invention will again depend upon the particular application and the amount of heat that will be generated, but should, of course, be high enough that the polymer does not melt or degrade during use.

As set forth above, the flexible heat dissipating composition of the present invention includes a hybrid filler material composed of 2D nanosheets made from a ceramic, carbon, or similar filler material and one or more organic molecules having two different functional groups capable of forming hydrogen or ionic bonds. As used herein the term “2D nanosheet” refers to nanosheets having a thickness of from about 2 nm to about 100 nm. 2D nanosheets are usually derived from exfoliation of 2-D materials having desired functional groups, but the application is not so limited and the 2D nanosheets may come from other sources as well. In one or more embodiments, may be formed from boron nitride, carbon, graphene oxide (GO), molybdenum disulfide or a combination thereof. In various embodiments, these 2D nanosheets are capable or form hydrogen or ionic bonds. In some embodiments, the 2D nanosheets will contain, or be functionalized to contain, functional groups capable of forming hydrogen or ionic bonds including, but not limited to, hydroxyl groups, carboxyl groups, amine groups, thiol groups, or any combinations thereof.

In one or more embodiments, the 2D nanosheets have a thickness of from about 2 nM to about 30 nM. In some embodiments, the 2D nanosheets have a thickness of from about 5 nM to about 30 nM, in other embodiments, from about 10 nM to about 30 nM, in other embodiments, from about 15 nM to about 30 nM, in other embodiments, from about 20 nM to about 30 nM, in other embodiments, from about 25 nM to about 30 nM, in other embodiments, from about 2 nM to about 25 nM, in other embodiments, from about 2 nM to about 20 nM, in other embodiments, from about 2 nM to about 15 nM, in other embodiments, from about 2 nM to about 10 nM, and in other embodiments, from about 2 nM to about 5 nM. Here, as well as elsewhere in the specification and claims, individual range values can be combined to form additional non-disclosed ranges.

In one or more embodiments, the 2D nanosheets have a length of from about 250 nM to about 1500 nM. In some embodiments, the 2D nanosheets have a length of from about 300 nM to about 1500 nM, in other embodiments, from about 500 nM to about 1500 nM, in other embodiments, from about 1000 nM to about 1500 nM, in other embodiments, from about 1250 nM to about 1500 nM, in other embodiments, from about 300 nM to about 1400 nM, in other embodiments, from about 300 nM to about 1200 nM, in other embodiments, from about 300 nM to about 1000 nM, in other embodiments, from about 300 nM to about 800 nM, and in other embodiments, from about 300 nM to about 400 nM. Here, as well as elsewhere in the specification and claims, individual range values can be combined to form additional non-disclosed ranges.

In one or more embodiments, the 2D nanosheets will comprise from about 0.1 to about 5 weight percent of the flexible heat dissipating composition. In some embodiments, the flexible heat dissipating composition will contain from about 0.05 wt % to about 5.0 wt %, in other embodiments, from about 1.0 wt % to about 5.0 wt %, in other embodiments, from about 2.0 wt % to about 5.0 wt %, in other embodiments, from about 3.0 wt % to about 5.0 wt %, in other embodiments, from about 0.1 wt % to about 4.0 wt %, in other embodiments, from about 0.1 wt % to about 3.0 wt %, in other embodiments, from about 0.1 wt % to about 2.0 wt %, in other embodiments, from about 0.1 wt % to about 1.5 wt %, and in other embodiments, from about 0.1 wt % to about 1.0 wt %, boron nitride 2D nanosheets. In some other embodiments, the flexible heat dissipating composition will contain from about 0.1 wt % to about 3.0 wt % boron nitride 2D nanosheets. Here, as well as elsewhere in the specification and claims, individual range values can be combined to form additional non-disclosed ranges.

As set forth above, the hybrid filler further includes one or more small organic molecules having two functional groups capable of forming hydrogen or ionic bonds. As set forth above, functional groups capable of forming hydrogen or ionic bonds may include, but is not limited to, hydroxyl groups, carboxyl groups, amine groups, thiol groups, or any combinations thereof. In some embodiments, these two functional groups may be the same, but that need not be the case. In some other embodiments, the two functional groups capable of forming hydrogen or ionic bonds may be different. In various embodiments, suitable organic molecules may include, without limitations, ethanolamine, ethylene diamine, ethylene glycol, diethylene glycol, tetra ethylene glycol, hexa ethylene glycol, poly ethylene glycol, dicarboxylic acids, and combinations thereof. In one or more of these embodiments, the organic molecules will be a C₂-C₆ linear alkane having terminal hydroxyl and amine functional groups. In some other embodiments, the organic molecules will be a C₂-C₆ linear alkane having two terminal hydroxyl functional groups. In other embodiments, the organic molecules will be a C₂-C₆ linear alkane having two terminal amine functional groups.

In one or more embodiments, the organic molecules will comprise from about 5 to about 60 weight percent (wt %) of said flexible heat dissipating composition. In some embodiments, the organic molecules will comprise from about 10 to about 60 weight percent (wt %), in other embodiments, from about 5 wt % to about 50 wt %, in other embodiments, from about 5 wt % to about 40 wt %, in other embodiments, from about 5 wt % to about 30 wt %, in other embodiments, from about 5 wt % to about 20 wt %, in other embodiments, from about 10 wt % to about 50 wt %, in other embodiments, from about 20 wt % to about 50 wt %, in other embodiments, from about 30 wt % to about 50 wt %, and in other embodiments, from about 40 wt % to about 50 wt %, of the flexible heat dissipating composition. In some embodiments, flexible heat dissipating composition will contain from about 2 wt % to about 40 wt % ethanolamine. In some other embodiments, the organic molecules will comprise from about 20 wt % to about 40 wt % ethanolamine. Here, as well as elsewhere in the specification and claims, individual range values can be combined to form additional non-disclosed ranges.

As set forth above, addition of the hybrid filler materials described above provides an optically clear and flexible heat dissipating composition with greatly improved heat dissipation properties relative to the neat polymer. In various embodiments, the optically transparent flexible heat dissipating composition of the present invention will have a thermal conductivity of from about 0.4 W/m·K to about 1.0 W/m·K. In some embodiments, heat dissipating polymer composition of the present invention will have a thermal conductivity of from about 0.5 W/m·K to about 1.0 W/m·K, in other embodiments, from about 0.6 W/m·K to about 1.0 W/m·K, in other embodiments, from about 0.7 W/m·K to about 1.0 W/m·K, in other embodiments, from about 0.8 W/m·K to about 1.0 W/m·K, in other embodiments, from about 0.3 W/m·K to about 0.9 W/m·K, in other embodiments, from about 0.4 W/m·K to about 0.8 W/m·K, in other embodiments, from about 0.4 W/m·K to about 0.7 W/m·K, in other embodiments, from about 0.4 W/m·K to about 0.6 W/m·K, and in other embodiments, from about 0.4 W/m·K to about 0.5 W/m·K. Here, as well as elsewhere in the specification and claims, individual range values can be combined to form additional non-disclosed ranges.

Further, the heat dissipating composition of the present invention are flexible compared to the neat polymer, and particularly when compared to known heat dissipating materials. As set forth before, many known polymer based heat dissipating used high loadings of traditional filler materials (ceramic/metallic/carbon) that tended to make these material hard and brittle. In various embodiments of the present invention, however, the introduction of the hybrid fillers described above results in the formation of elastic thermal network which is mainly made up of hydrogen and/or ionic bonds. While not wishing to be bound by theory, it is believed that the relatively weak hydrogen bonds between the polymer, organic filler material, and 2D nanosheets can break and reform allowing the 2D nanosheets to slide over each other allowing heat dissipating composition flex without damage.

In one or more embodiments, the heat dissipating compositions of the present invention will have an elongation of from about 50% to about 500% as measured by a tensiometer. In some embodiments, the heat dissipating compositions of the present invention will have an elongation of from about 100% to about 500%, in other embodiments, from about 150% to about 500%, in other embodiments, from about 200% to about 500%, in other embodiments, from about 250% to about 500%, in other embodiments, from about 300% to about 500%, in other embodiments, from about 50% to about 400%, in other embodiments, from about 50% to about 350%, in other embodiments, from about 50% to about 300%, in other embodiments, from about 50% to about 250%, from about 50% to about 200%, and in other embodiments, from about 50% to about 150%, as measured by a tensiometer. This level of elongation is rare for traditional materials, where elongation is generally only 10-50%. Here, as well as elsewhere in the specification and claims, individual range values can be combined to form additional non-disclosed ranges.

Further, it has been found that the use of the organic molecules (a non-traditional filler material) that are miscible with the polymer gives these heat dissipating compositions their transparency. Moreover, as set forth above, traditional filler materials are opaque and, as a result, using a high loading of any traditional filler material will make heat dissipating compositions opaque. Because the heat dissipating compositions of the present invention do not rely upon a high loading of traditional (opaque) fillers to provide the thermal conductivity, they remain optically clear.

In a second aspect, the present invention is directed to a flexible, optically transparent heat dissipating film or coating using the flexible heat dissipating composition described above. In some embodiments, it is a freestanding film. In some other embodiments, the present invention may be a surface coating. In various embodiments, the optically clear flexible heat dissipating composition described above, may be formed into a film or coating by any method known in the art for that purpose, including but not limited to, solvent casting, dip coating, doctor blade casting, or spin coating.

The thickness of the films or coatings that may be formed from the optically transparent, flexible heat dissipating of the present invention is not particularly limited. In some embodiments, the optically transparent heat dissipating film or coating of the present invention will have a thickness of from about 10 microns to 1 cm. In some embodiments, the optically transparent heat dissipating film or coating of the present invention will have a thickness of from about 1000 μm to about 10,000 μm, in other embodiments, from about 1000 μm to about 10,000 μm, in other embodiments, from about 1000 μm to about 10,000 μm, in other embodiments, from about 1000 μm to about 10,000 μm, in other embodiments, from about 1000 μm to about 10,000 μm, in other embodiments, from about 1000 μm to about 10,000 μm, in other embodiments, from about 1000 μm to about 10,000 μm, in other embodiments, from about 1000 μm to about 10,000 μm, in other embodiments, from about 1000 μm to about 10,000 μm, and in other embodiments, from about 1000 μm to about 10,000 μm. Here, as well as elsewhere in the specification and claims, individual range values can be combined to form additional non-disclosed ranges.

In various embodiments, flexible, optically transparent heat dissipating film or coatings present many advantages over films and coatings made using comparable prior art heat dissipation materials. They are highly elastic and optically clear making then suitable for many flexible electronics and thermal management applications. They are also cheaper to produce because they do not require the high loadings of traditional fillers, many of which are expensive. As set forth only one filler component is a traditional filler material (generally, the material forming the 2D nanosheets), and it is only present at a relatively small loading. As they do not have the high loadings of traditional filler materials they are also much lighter weight than traditional polymer composites and can be easily fabrication to various films of varied shapes and sizes.

Further, as will be appreciated, polymers are usually non-corrosive and are frequently used in industry as corrosion resistance coatings. In addition, both organic fillers and fillers like boron nitride are ceramic and highly non-reactive materials. Not surprisingly, the flexible, optically transparent heat dissipating film or coatings of the present invention have also been found to be non-corrosive.

In a third aspect, the present invention is directed to a method for producing the flexible heat dissipating composition described above. In these embodiments, a polymer capable of forming hydrogen or ionic bonds as described above is selected and dissolved in a suitable solvent. In various embodiments, the polymer used will form a substantially clear solution when fully dissolved. The solvent is not particularly limited provided that both the polymer and organic filler are fully soluble in the solvent at operational temperatures, pressures and concentrations. As will be appreciated, the suitability of a solvent will, of course, depend upon the particular polymer chosen. Suitable solvents may include, without limitation, deionized water, organic and inorganic solvents. One or ordinary skill in the art will be able to select a suitable solvent without undue experimentation. As will be appreciated by those of ordinary skill in the art, it may be necessary to dissolve the polymer at an elevated temperature and/or for over an extended period of time, as is known in the art. In some embodiments, it will be necessary to heat the polymer above its glass transition temperature before it can be dissolved in a particular solvent. For example, in some embodiments the polymer selected is polyvinyl alcohol (PVA) and it is dissolved in deionized water at about 90° C. to about 95° C. for from 0.5 to about 5 hours or until the solution becomes clear.

Next, one of the materials described above is selected to form the 2D nanosheets. As will be appreciated by those of ordinary skill in the art, these materials are generally exfoliated to form a slurry of 2D nanosheets having a desired size and thickness. In some embodiments, the 2D nanosheets may be suspended in water for use. These materials may be exfoliated using any method known in the art for that purpose, but are preferably exfoliated using a wet ball milling process with NaOH, has is known in the art. In these embodiments, the NaOH is then removed and the slurry centrifuged. As will be appreciated, the 2D nanosheets are very small and will be suspended in the supernatant, which is then collected for use. The 2D nanosheets will have, or be functionalized to have, one or more functional groups capable of forming hydrogen or ionic bonds. One of ordinary skill in the art will be able to add one or more functional groups capable of forming hydrogen or ionic bonds to the 2D nanosheets without undue experimentation. In some embodiments, functional groups capable of forming hydrogen or ionic bonds may be added during the exfoliation process by milling with a milling agent having the desired functional group (e.g., NaOH for OH groups and urea for NH₂ groups). By way of example, in some embodiments, hexagonal boron nitride is combined with NaOH and ball milled for from 1 to about 24 hours at a speed of from about 200 RPM to about 700 RPM to form a slurry. The dissolved NaOH is then removed from the slurry. The NaOH may be removed by any conventional method. In some embodiments, the slurry is centrifuged and the supernatant containing NaOH and water are removed. The BN is then ultra-sonicated in water for about 1 hour. The ultra-sonicated product is then centrifuged at about 2000 RPM for about 3 minutes and the resulting supernatant containing the boron nitride 2D nanosheets surface functionalized with one or more functional groups capable of forming hydrogen or ionic bonds is collected.

Finally, one of the organic molecules described above having two different functional groups capable of forming hydrogen or ionic bonds is selected and is added to the polymer solution with the 2D nanosheets. The mixture is then stirred or agitated for from about 0.5 hours to about 5 hours at a temperature of from about 40° C. to about 80° C. to form the flexible heat dissipating composition.

In one or more of these embodiments, from about 0.1 wt % to about 5 wt % of boron nitride 2D nanosheets and from 5 wt % to about 60 wt % of ethanolamine are added to a clear solution of PVA and stirred or agitated for from about 0.5 hours to about 5 hours at a temperature of from about 40° C. to about 80° C. to form an optically clear flexible heat dissipating composition according to the present invention. In some of these embodiments, from about 0.1 wt % to about 5 wt % of boron nitride 2D nanosheets, in other embodiments, from about 0.1 wt % to about 3 wt %, in other embodiments, from about 0.1 wt % to about 2 wt %, in other embodiments, from about 0.5 wt % to about 5 wt %, and in other embodiments, from about 1 wt % to about 5 wt % may be used. While these materials maintain their flexibility, it has been found that the optical clarity of these flexible heat dissipating compositions begins to decrease at boron nitride loading over 5 wt %. In some embodiments, from 5 wt % to about 60 wt %, in other embodiments, from 5 wt % to about 50 wt %, in other embodiments, from 5 wt % to about 40 wt %, in other embodiments, from 5 wt % to about 30 wt %, in other embodiments, from 10 wt % to about 20 wt %, in other embodiments, from 15 wt % to about 50 wt %, in other embodiments, from 20 wt % to about 50 wt %, in other embodiments, from 30 wt % to about 50 wt %, in other embodiments, from 40 wt % to about 50 wt % of ethanolamine may be used. Here, as well as elsewhere in the specification and claims, individual range values can be combined to form additional non-disclosed ranges.

In a forth aspect, the present invention is directed to a method for producing a flexible, optically transparent heat dissipating film from the optically transparent flexible heat dissipating composition described above. In these embodiments, an optically clear flexible heat dissipating composition according to the present invention is prepared as set forth above. The optically clear flexible heat dissipating composition is then poured the into a flat-bottomed container or onto a surface and dried it at a temperature of from about 25° C. to about 60° C. for from 1 to 7 days to form a freestanding film. Care should be taken not to dry the films so quickly as to create imperfections in the film. In some of these embodiments, the dried films are then heated again to remove any remaining moisture or solvent. In some of these embodiments, the films are at a temperature of from about 40° C. to about 80° C. for from 1 to 24 hours to remove any remaining moisture or solvent.

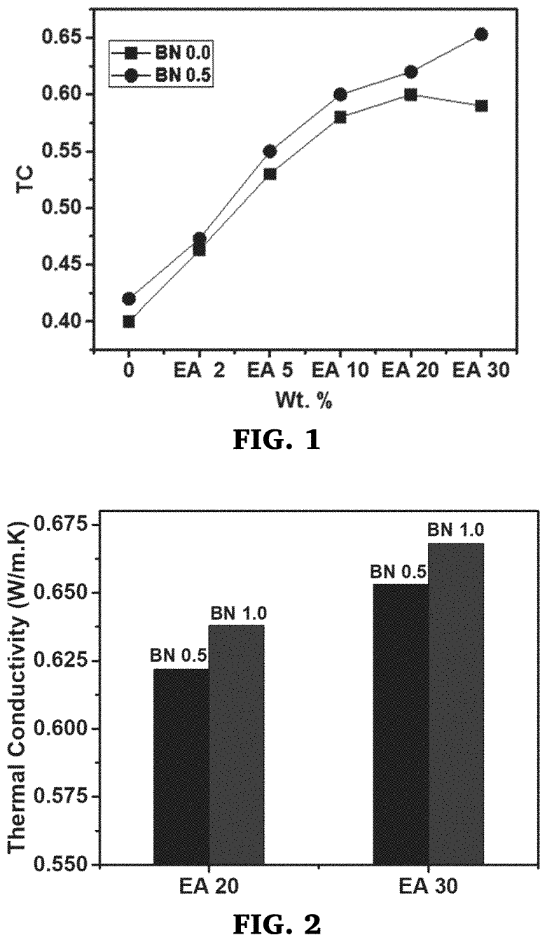

To further evaluate the flexible heat dissipating materials of the present invention and further reduce them to practice, a series of a series of flexible heat dissipating materials comprising a polyvinyl alcohol (PVA) polymer and different loadings of boron nitride (BN) and ethanolamine (EA) were formed as set forth above and tested. In a first set of tests, the impact of the BN on the thermal conductivity of PVA polymer films at different loadings of EA was evaluated. In these experiments, sets of films having 2 wt %, 5 wt %, 10 wt %, 20 wt %, and 30 wt % EA with 0.5 wt % BN and without BN were prepared as set forth above and cross-plane thermal conductivity measurements taken using C-Therm TCi Thermal Conductivity Analyzer. As will be apparent to those of skill in the art, the TCi analyzer works on a modified transient plane source technique (Conforms to ASTM D7984 (2016)) and its sensor acts as a heat source approximating heat flow in one dimension. The results of these experiments are shown in FIG. 1.

As can be seen, even in very small amounts, the present of the BN improved the thermal conductivity of the films at all loading of EA, and particularly at EA loadings of 30 wt %. Combination of both BN nanosheet and EA, lead to the formation of good thermal networks owing to intermolecular interactions like hydrogen bonding present between them. Such intermolecular interactions can lead to the formation of thermal bridges between PVA, EA and BN nanosheets. It is believed that such interactions also help to lower interfacial thermal resistance between polymer and BN nanosheets which in turn facilitates efficient thermal conduction.

In another set of experiments, films were prepared with at a 1.0 wt % and a 0.5 wt % loading of BN and different loading EA (20 wt % and 30 wt %) and cross-plane thermal conductivity measurements taken using C-Therm TCi Thermal Conductivity Analyzer as set forth above. The results of these experiments are shown in FIG. 2. As can be seen, increase in the loading from 0.5 wt % to 1.0 wt % resulted in an increase in the thermal conductivity of these films at both 20 wt % and 30 wt % EA.

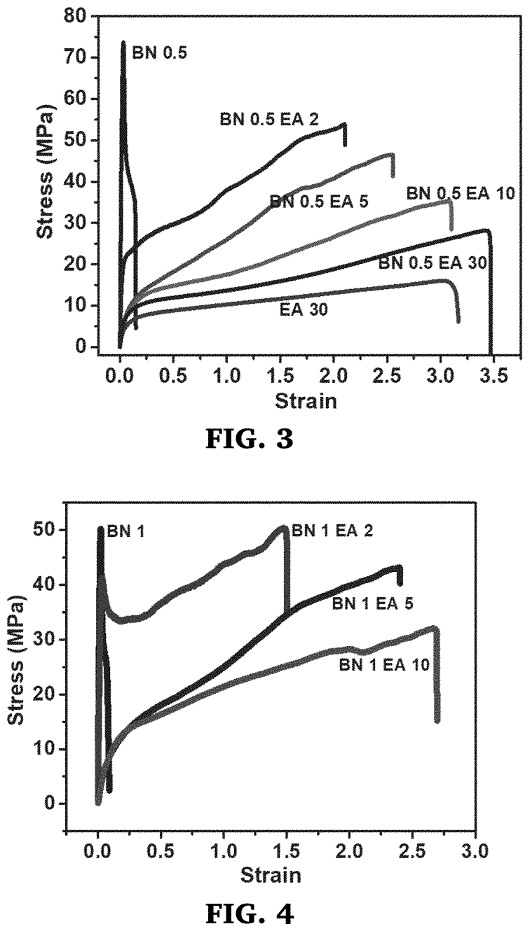

To evaluate the flexibility of these materials, a series of films having 2 wt %, 5 wt %, 10 wt %, 20 wt %, and 30 wt % EA with 0.5 wt % BN were prepared and subjected to mechanical testing using ADMET 500 universal testing machine (MTEST Quattro, USA). The stress-strain curves for these materials are shown in FIG. 3. As can be seen, the flexible heat dissipating materials of the present invention using BN, EA and PVA provided heat dissipation materials with excellent elongation of around 350% (BN 0.5 EA 30). This degree of was unexpected and would be rare for traditional material, where elongation is usually about 10-50% as their as the high loading of traditional filler materials in the polymer of these materials generally make them brittle.

For comparison purposes, flexible heat dissipating films having 2 wt %, 5 wt %, and 10 wt %, EA with 1.0 wt % BN were prepared and tested. The stress-strain curves for these materials are shown in FIG. 4. As can be seen, elongation increases with the increase of EA loading, which demonstrates the importance of both EA/BN nanosheets in developing an elastic network in the polymer composite.

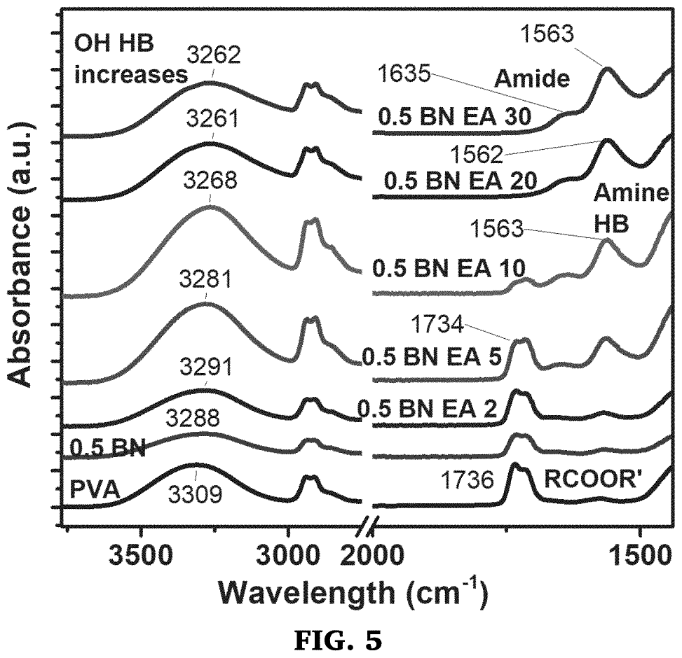

To study the intermolecular interactions and functional groups, FT-IR characterizations were carried out on a film prepared with only PVA polymer, a film prepared with 0.5 wt % BN and no EA, and films prepared with 2 wt %, 5 wt %, 10 wt %, 20 wt %, and 30 wt % EA with 0.5 wt % BN using a Perkin Elmer Frontier FT-IR spectrometer. The results are shown in FIG. 5. As can be seen, various peaks of amine, amide, OH etc. are present in the composite film owing to different functional groups of filler, matrix and interactions between them. OH peak gradually shifted from 3309 cm⁻¹ to 3262 cm⁻¹ signifying the change in intermolecular interaction between OH of PVA and fillers as the loading of EA is increased.

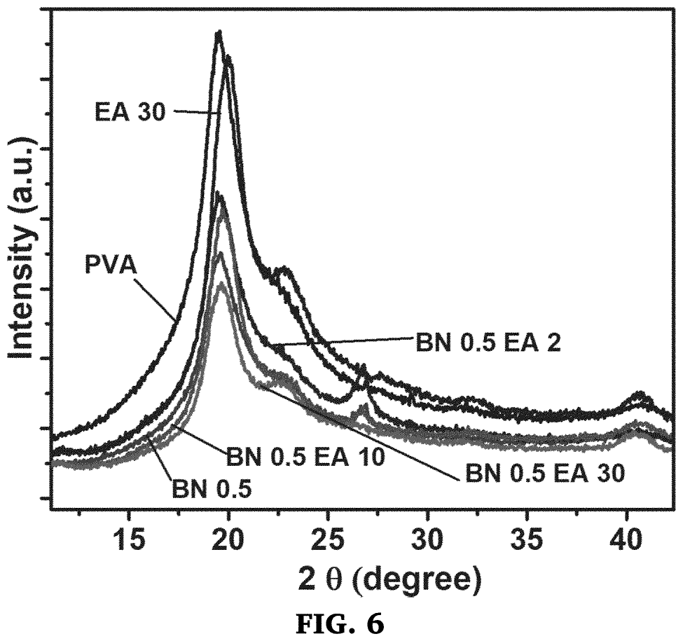

To examine the crystalline properties, X-ray diffraction (XRD) analysis was carried out on a film prepared with only PVA polymer, a film prepared with 0.5 wt % BN and no EA, and films prepared with 2 wt %, 10 wt %, and 30 wt % EA with 0.5 wt % BN, using a Bruker AXS D8 Discover diffractometer with GADDS (General Area Detector Diffraction System) operating with a Cu-Kα radiation source filtered with a graphite monochromator (λ=1.541 Å). The results are shown in FIG. 6. As can be seen, the peak of neat PVA at around 2θ=20° gradually decreases as the loading of EA is increased. This peak is the signature peak of neat PVA for its semi-crystalline nature due to intense intra/inter-hydrogen bonding. Decrease in peak signifies that inter/intra hydrogen bonds in neat PVA are replaced with new interactions due to the presence of EA and exfoliated 2D BN sheets. Such interactions both lead to good thermal network as well as flexibility.

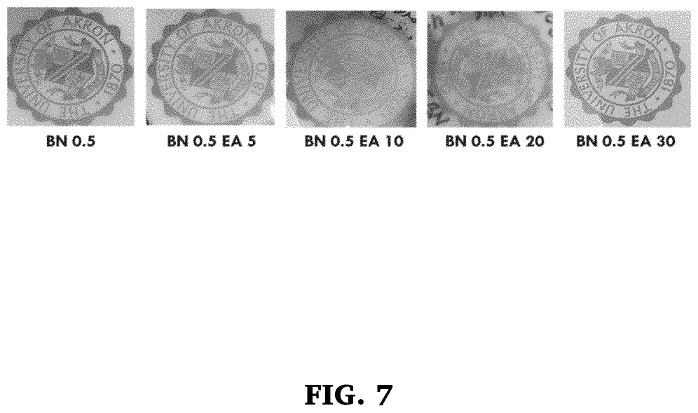

To show the optical clarity of these films, photographs were taken comparing PVA films prepared as set forth above with BN and EA placed on the University of Akron seal. The results are shown in FIG. 7. As can be seen, all the plastic films were optically transparent. Transparency increases as the loading of EA is increased in hybrid films. The film having 0.5 wt % of BN and 30 wt % of EA is very clear.

### EXAMPLES

The following examples are offered to more fully illustrate the invention, but are not to be construed as limiting the scope thereof. Further, while some of examples may include conclusions about the way the invention may function, the inventor do not intend to be bound by those conclusions, but put them forth only as possible explanations. Moreover, unless noted by use of past tense, presentation of an example does not imply that an experiment or procedure was, or was not, conducted, or that results were, or were not actually obtained. Efforts have been made to ensure accuracy with respect to numbers used (e.g., amounts, temperature), but some experimental errors and deviations may be present. Unless indicated otherwise, parts are parts by weight, molecular weight is weight average molecular weight, temperature is in degrees Centigrade, and pressure is at or near atmospheric.

### Materials

Poly-vinyl alcohol (PVA) was purchased from Sigma-Aldrich having average molecular weight of 146,000-186,000 g/mol with degree of hydrolysis of 87-89%. Ethanolamine (EA) was purchased from Sigma-Aldrich and hexagonal boron nitride was purchased from Saint-Gobain Ceramics. Deionized water (Millipore) having a minimum resistivity of 18.2 MΩ·cm was used in all the experiments. All materials were used as received without further purification.

### Example 1

### Preparation of Exfoliated BN

Exfoliation of BN was carried out using sodium hydroxide assisted wet milling using Emax (Retsch, Germany) ball miller. Briefly, 1 gm of BN was mixed with 5 ml of 2 M NaOH solution and ball milled for 24 hours at 500 RPM. The obtained slurry was washed several times using high speed centrifuge to remove dissolved NaOH. Then it was further subjected to 1 hour of ultra-sonication in water. The ultra-sonicated BN solution was centrifuge at 2000 RPM for 30 min and supernatant was collected with represents exfoliated BN denoted as BN.

### Example 2

### Preparation of PVA Composite Films

Solvent casting method was used to prepare pure PVA and PVA composite films. Required amount of PVA was first dissolved in DI water at 90-95° C. for 5 hours to make 8% aq. PVA solution under constant magnetic stirring. After obtaining clear aqueous PVA solution, it was poured in glass petri dish and dried at 35° C. for 4 days to obtain freestanding films and later heated at 60° C. for another 1 day. Preparation of composite film samples was done through mixing clear aq. PVA solution with different weight percentage of EA and BN under magnetic stirrer for 3 hours at 75-80° C. Free standing composite films were obtained with similar method as pure PVA films. The term EA X represents composite films with X wt % loading of EA into PVA solution whereas BN X EA Y represents combined mixing of X wt % of BN and Y wt. % of EA in PVA solution.

In light of the foregoing, it should be appreciated that the present invention significantly advances the art by providing a flexible, optically transparent heat dissipating material that is structurally and functionally improved in a number of ways. While particular embodiments of the invention have been disclosed in detail herein, it should be appreciated that the invention is not limited thereto or thereby inasmuch as variations on the invention herein will be readily appreciated by those of ordinary skill in the art. The scope of the invention shall be appreciated from the claims that follow.

What is claimed is:

1. A flexible heat dissipating composition comprising:
a substantially electrically non-conductive polymer comprising one or more functional groups capable of forming hydrogen or ionic bonds; and
a hybrid filler comprising:
one or more ceramic 2D nanosheets surface functionalized with one or more functional groups capable of forming hydrogen or ionic bonds; and
one or more organic molecules having two different functional groups capable of forming hydrogen or ionic bonds.

2. The flexible heat dissipating composition of claim 1 wherein the substantially electrically non-conductive polymer, one or more ceramic 2D nanosheets, and one or more organic molecules are connected to each other by hydrogen bonds to form an interpenetrating network.

3. The flexible heat dissipating composition of claim 1 wherein said composition is optically transparent.

4. The flexible heat dissipating composition of claim 1 wherein said substantially electrically non-conductive polymer is selected from the group consisting of poly(vinyl alcohol), polyvinyl propylene, polyether, polyamide, polyacrylic amides, polysaccharides, polyacrylic acids, polyurethanes with polyethylene glycol ether soft segments, and combinations, copolymers and grafts thereof.

5. The flexible heat dissipating composition of claim 1 wherein the one or more functional groups capable of forming hydrogen or ionic bonds in said substantially electrically non-conductive polymer are selected from hydroxyl groups, carboxyl groups, amine groups, thiol groups, and combinations thereof.

6. The flexible heat dissipating composition of claim 1 wherein said one or more ceramic 2D nanosheets comprise boron nitride, carbon, graphene oxide (GO), molybdenum disulfide or a combination thereof.

7. The flexible heat dissipating composition of claim 1 wherein said one or more ceramic 2D nanosheets have a thickness of from about 2 nM to about 30 nM.

8. The flexible heat dissipating composition of claim 1 wherein said one or more ceramic 2D nanosheets have a length of from about 250 nM to about 1500 nM.

9. The flexible heat dissipating composition of claim 1 wherein said one or more ceramic 2D nanosheets comprise from about 0.1 to about 5 weight percent of said flexible heat dissipating composition.

10. The flexible heat dissipating composition of claim 1 wherein said one or more organic molecules comprise a C₂-C₆ linear alkane having a first end comprising a hydroxyl functional group and a second end comprising an amine functional group.

11. The flexible heat dissipating composition of claim 1 wherein said one or more organic molecules is selected from the group consisting of ethanolamine, ethylene diamine, ethylene glycol, diethylene glycol, tetra ethylene glycol, hexaethylene glycol, dicarboxylic acids, crystalline sugars, amino acids, and combinations thereof.

12. The flexible heat dissipating composition of claim 1 wherein said one or more organic molecules comprise from about 5 to about 60 weight percent (wt %) of said flexible heat dissipating composition.

13. The flexible heat dissipating composition of claim 1 having a thermal conductivity of from about 0.4 W/m·K to about 1.0 W/m·K.

14. The flexible heat dissipating composition of claim 1 having an elongation of from about 50% to about 500%.

15. A flexible, optically transparent heat dissipating film or coating comprising the flexible heat dissipating composition of claim 3.

16. The flexible, optically transparent heat dissipating film or coating of claim 15 comprising from about 0.2 wt % to about 5 wt % boron nitride and from about 20 wt % to about 40 wt % ethanolamine.

17. The flexible, optically transparent heat dissipating film or coating of claim 15 wherein said flexible, optically transparent heat dissipating film or coating is a free-standing film.

18. The flexible, optically transparent heat dissipating film or coating of claim 15 having a thickness of from about 10 microns to 1 cm to about 80 nM.

19. The flexible, optically transparent heat dissipating film or coating of claim 15 formed by solvent casting dip coating, doctor blade casting, or spin coating.

20. A method for producing the flexible heat dissipating composition of claim 1, comprising:
A) selecting a substantially electrically non-conductive polymer having one or more functional groups capable of forming hydrogen or ionic bonds;
B) dissolving said substantially electrically non-conductive polymer in a suitable solvent;
C) preparing ceramic 2D nanosheets surface functionalized with one or more functional groups capable of forming hydrogen or ionic bonds;
D) selecting a suitable organic filler material having at least two functional groups capable of forming hydrogen or ionic bonds;
E) adding the ceramic 2D nanosheets of step C and the organic filler material of Step D to the substantially electrically non-conductive polymer solution of step B and stirring or agitating for from about 0.5 hours to about 5 hours at a temperature of from about 40° C. to about 80° C. to form the flexible heat dissipating composition of claim 1.

21. The method of claim 20, wherein the step of stirring or agitating comprises stirring or agitation for from about 0.5 hours to about 5 hours at a temperature of from about 40° C. to about 80° C.

22. The method of claim 20, wherein the substantially electrically non-conductive polymer is selected from the group consisting of polyvinyl alcohol, polyvinyl propylene, polyether, polyamide, polyacrylic amides, polysaccharides, polyacrylic acids, polyurethanes with polyethylene glycol ether soft segments, and combinations, copolymers, or graft thereof.

23. The method of claim 20, wherein said substantially electrically non-conductive polymer in polyvinyl alcohol and the step of dissolving said substantially electrically non-conductive polymer (step B) comprises dissolving polyvinyl alcohol in deionized water at about 90° C. to about 95° C. for from 0.5 to about 5 hours or until the solution becomes clear.

24. The method of claim 20, wherein said ceramic 2D nanosheets comprise a ceramic material selected from the group consisting of boron nitride, carbon, graphene oxide (GO), molybdenum disulfide, and combinations thereof.

25. The method of claim 20, wherein the ceramic 2D nanosheets comprise boron nitride and the step of preparing the ceramic 2D nanosheets (step C) comprises:
1. combining hexagonal boron nitride with NaOH and ball milling for from 1 to about 24 hours at a speed of from about 200 RPM to about 700 RPM to form a slurry;
2. removing the dissolved NaOH from the slurry of step (a);
3. subjecting the product of step (b) to ultra-sonication in water for about 1 hour;
4. centrifuging the ultra-sonicated product of step (c) and collecting the supernatant containing the boron nitride 2D nanosheets surface functionalized with one or more functional groups capable of forming hydrogen or ionic bonds.

26. The method of claim 20, wherein the organic filler material comprises an organic material selected from the group consisting of ethanolamine, ethylene diamine, ethylene glycol, diethylene glycol, tetra ethylene glycol, hexaethylene glycol, dicarboxylic acids, crystalline sugars, amino acids, and combinations thereof.

27. A method for producing a flexible, optically transparent heat dissipating film comprising the optically transparent flexible heat dissipating composition according to claim 3 comprising:
A) dissolving a polymer selected from the group consisting of poly(vinyl alcohol), polyvinyl propylene, polyether, polyamide, polyacrylic amides, polysaccharides, polyacrylic acids, polyurethanes with polyethylene glycol ether soft segments, and combinations, copolymers, or graft thereof in a suitable solvent to obtain a clear polymer solution;
B) preparing 2D nanosheets comprising one or more of boron nitride, carbon, graphene oxide (GO), and molybdenum disulfide, said 2D nanosheets being surface functionalized with one or more functional groups capable of forming hydrogen or ionic bonds;
C) adding from 0.1 wt % to about 5 wt % the 2D nanosheets of step B and from 5 wt % to about 60 wt % of an organic filler material comprising an organic compound selected from the group consisting of ethanolamine, ethylene diamine, ethylene glycol, diethylene glycol, tetra ethylene glycol, hexaethylene glycol, dicarboxylic acids, crystalline sugars, amino acids, and combinations thereof to the clear polymer solution of step A and stirring or agitating for from about 0.5 hours to about 5 hours at a temperature of from about 40° C. to about 80° C. to form the optically clear flexible heat dissipating composition of claim 3;
D) pouring the optically clear flexible heat dissipating composition of step C into a flat-bottomed container or onto a surface and drying it at a temperature of from about 25° C. to about 60° C. for from 1 to 7 days to form a freestanding film; and
E) heating said freestanding film of step E at a temperature of from about 40° C. to about 80° C. for from 1 to 24 hours to remove any remaining solvent.
